(19) United States
(12) Patent Application Publication
(10) Pub. No.: US 2005/0139915 A1
(43) Pub. Date: Jun. 30, 2005

(54) Recording medium for recording simulation model data for semiconductor circuit and method of simulating semiconductor circuit

(76) Inventors: Takashi Saito, Takasaki (JP); Hitoshi Sugihara, Takasaki (JP); Saiko Kobayashi, Takasaki (JP)

Correspondence Address: MATTINGLY, STANGER & MALUR, P.C.;ATTORNEYS AT LAW, 1800 DIAGONAL ROAD, SUITE 370, ALEXANDRIA, VA, 22314, US

(21) Appl. No.: 11/019,273

(22) Filed: Dec. 23, 2004

(30) Foreign Application Priority Data
Dec. 26, 2003 (JP) 2003-433091

(51) Int. Cl. H01L 29/76; H01L 21/336

(52) U.S. Cl. 257/346; 438/299; 257/387

(57) ABSTRACT

An element model of a high voltage MOS transistor having a low concentration impurity region between a channel region thereof and a drain electrode thereof is defined by combining a plurality of element models with each other. A basic characteristic is represented by a standard MOS model. A conductivity modulation effect of a low concentration drain diffusion layer is represented by a variable resistor model whose value is changed based upon both a drain voltage and a gate voltage. An overlap capacitance between a gate region and a drain region is represented by a MOS capacitance between the gate region and a bulk. A variable resistor model compensates that a voltage of channel edge portions located adjacent to the low concentration drain diffusion layer is changed by being influenced by not only the gate voltage, but also the drain voltage.

### INCORPORATION BY REFERENCE

The present application claims priority from Japanese application JP2003-433091 filed on Dec. 26, 2003, the content of which is hereby incorporated by reference into this application.

### BACKGROUND OF THE INVENTION

The present invention is related to an element model of a high voltage MOS transistor having a low concentration impurity region between a channel region thereof and a drain electrode thereof, and is directed to a technique which is effectively applied to, for instance, a recording medium which has stored thereinto model types of element models and model parameters, and also applied to a circuit simulation using information recorded on this recording medium.

The Inventors of the present invention become aware of the below-mentioned patent publications after the present invention has been accomplished. JP-A-2000-307096 (FIG. 1) (will be referred to as “patent publication 1” hereinafter) describes such a MOS type transistor. That is, generally speaking, since a MOS type transistor normally employs an LDD (Lightly Doped Drain) structure capable of reducing impurity concentration of a source region thereof and a drain region thereof, which are overlapped with a gate electrode region, electric field concentration at this LDD structure is lessened and a drain blocking voltage is improved. However, since carrier concentration of a low concentration impurity region is low, when a high gate voltage, a high drain voltage, and a high source voltage are applied which are approximated to 20 V, the carrier concentration is largely influenced by the adverse influence of these electric fields, the LDD region may give an effect to the MOS type transistor as a resistance component in which the resistance value varies depending upon the applied voltage. In this patent publication 1, the following fact could be found out. That is, in particular, when variation widths of a gate voltage and a source voltage during circuit operation in a device designed in a high voltage specification are large such as 0 to 18 V, a change in stray resistance values produced in the LDD low concentration impurity region is actually increased. As a result, since an error between an actual measurement value of a transistor characteristic and a simulation value of the transistor characteristic becomes large, it is practically difficult that the simulation characteristic is matched with the actual measurement value. This patent publication 1 discloses such a circuit simulation method as a solving measurement for this difficulty. In this circuit simulation method, while an entire gate voltage region is subdivided into a plurality of gate voltage regions, a proper element model having a fixed resistance is used every gate voltage region.

Also, JP-A-2000-250958 (FIG. 1, paragraph 11) (will be referred to as “patent publication 2” hereinafter) describes the following technical idea. That is, in a field-effect transistor model which is used in a radio frequency (RF) output circuit, a series circuit constituted by an RF output resistor and a capacitor indicative of a time constant used to represent an RF output is connected between a source and a drain of this field-effect transistor model, and this RF output resistor is changed in response to a gate voltage of the field-effect transistor. In such a case that a large RF signal is inputted to the gate of the field-effect transistor, and thus, the gate voltage is swung to the negative side from a threshold voltage, this technical idea can decrease a channel conductance, as viewed from an RF characteristic, and can suppress an increase of a DC current component, so that simulation precision of an electric power load efficiency can be improved.

### SUMMARY OF THE INVENTION

The inventors of the present invention have investigated the element model of the high voltage MOS transistor having the low-concentration impurity region between the channel region and the drain region. As a result of the investigation, the Inventors could find out necessities of considering the following items in order to realize high-precision device simulation performance without requiring a huge amount of processing time by a computer: The voltage of the channel edge portion which is located adjacent to the low concentration drain diffusion layer is influenced by not only the gate voltage, but also the drain voltage to be therefore changed; the gate which is overlapped with the low concentration drain diffusion layer constitutes the stray capacitance; and also, these resistance component and capacitance component related to the low concentration drain diffusion layer are present in a distributed constant. In the technical idea described in the patent publication 1, since the element model of the fixed resistance is used every gate voltage region so as to execute the circuit simulation, in the case that a gate voltage is simulated, the gate voltage to be simulated is predicted and the element model of the fixed resistance to be used must be determined. The technical idea disclosed in the patent publication 2 is made based upon such a view point that while considering the influence of the conductance originally caused by the RF component of the gate input, this RF output resistance is changed by the gate voltage of the field-effect transistor. Accordingly, there is no common relationship between this technical idea and the element model of the high voltage MOS transistor having the low concentration impurity region between the channel region and the drain region.

An object of the present invention to provide an element model capable of reducing an error between an actual measurement value as to an element characteristic of a high voltage MOS transistor having a low concentration impurity region between a channel region thereof and a drain region thereof, and a simulation value of this element characteristic.

Another object of the present invention is to improve simulation precision of a circuit which employs the high voltage MOS transistor having the low concentration impurity region between the channel region thereof and the drain region thereof.

The above-described objects and other objects of the present invention, and nobel features thereof may be apparent from a description of the specification as well as the accompanying drawings.

[1]. A typical conceptional idea among the inventive ideas of the present invention will now be summarized. That is, an element model of a high voltage MOS transistor having a low concentration impurity region between a channel region thereof and a drain electrode thereof is defined by combining a plurality of element models (partial element models) with each other. A basic characteristic is represented by a standard MOS model (MMAIN). A conductivity modulation effect of a low concentration drain diffusion layer is represented by a variable resistor model (RDD, JFET, MOSR, VCI) whose value is changed based upon both a drain voltage and a gate voltage. An overlap capacitance between a gate region and a drain region is represented by a MOS capacitance between the gate region and a bulk. Subsequently, the present invention will be explained based upon the respective aspects.

[2]. A first aspect of the present invention is featured by such a recording medium for recording thereon computer-readable data as to an element model of a high voltage MOS (Metal Oxide Semiconductor) transistor having a low concentration impurity region between a channel region thereof an a drain region thereof, in which the element model owns a variable element model between the drain electrode and the channel region of the high voltage MOS transistor, the variable element model representing a change of a resistance value depending upon a drain voltage. The variable resistor model compensates that a voltage of channel edge portions located adjacent to the low concentration drain diffusion layer is changed by being influenced by not only the gate voltage, but also the drain voltage. This may be operated so as to reduce an error between an actual measurement value of an element characteristic of the high voltage MOS transistor and a simulation value thereof.

As one concrete mode of the present invention, the resistance value is also changed, depending upon a voltage applied to the gate electrode of the high voltage MOS transistor. In summary, a gate voltage (namely, gate-to-source voltage) is contained in a parameter of the variable element model. Also, the resistance value is also changed, depending upon a gate size of this high voltage MOS transistor and a temperature. In summary, both the gate size of the high voltage MOS transistor and the temperature are contained in the parameter of the variable element model.

As a more concrete mode of the present invention, the variable element model may be expressed by a variable resistor model, a junction FET model, a variable current source model, or a variable voltage source model etc. In summary, the variable element model may be represented as such a model which may function as a voltage-controlled current source, a voltage-controlled voltage source, a current-controlled current source, and a current-controlled voltage source.

As another concrete mode of the present invention, the high voltage MOS transistor is equipped with the low concentration impurity region between the channel region thereof and the drain electrode thereof as the above-described first featured structure, and also, owns an overlap region which is overlapped via a gate oxide film to a gate electrode in the low concentration impurity region as a second featured structure. The element model of the high voltage MOS transistor having this structure may be preferably represented in combination with the above-described variable element model by a MOS model which expresses a major characteristic with respect to the channel region of the high voltage MOS transistor; a capacitor model which expresses a capacitance characteristic of the overlap region of the high voltage MOS transistor; and a fixed resistor model which is arranged in series to the capacitor model. In an actual case, both the resistance component of the low concentration impurity region and the capacitance component of the overlap region are present in the distributed constant manner. When this distributed constant manner of the resistance/capacitance components is considered, such a expression that this resistance component is expressed by both the variable resistor and the fixed resistor may be properly adapted to an actual device characteristic, as compared with such an expression that this resistance component is expressed only by the variable resistor. A combination with the variable resistor is not made with another variable resistor, but is made with a fixed resistor, and also, is not represented by a distributed constant resistor, so that a large increase in process time by a computer can also be suppressed. The MOS capacitor model is expressed by a MOS capacitor model having a different conductivity type with respect to that of the MOS model, which may be properly adapted to the actual device structure.

As a further concrete example of the present invention, the element model is further comprised of: a diode model provided between the drain electrode and a substrate; a diode model provided between the drain electrode and a source electrode; an overlap capacitor model provided between the gate electrode and the drain electrode; and an overlap capacitor model provided between the gate electrode and the source electrode, which may be properly adapted to the actual device characteristic.

Since the element model of the above-described high voltage MOS transistor is stored in the computer-readable recording medium so as to be provided, the precision of the circuit simulation with respect to such a circuit using the high voltage MOS transistor can be readily improved, and also, the provided element model of the high voltage MOS transistor can contribute to improve reliability of designing the circuit with employment of the high voltage MOS transistor and also can contribute to shorten the designing term.

[3]. A second aspect of the present invention is featured by such a circuit simulation method for executing a circuit simulation with employment of an element model of a high voltage MOS transistor having a low concentration impurity region between a channel region thereof and a drain electrode thereof in which the element model owns a variable element model between the drain electrode and a source electrode of the high voltage MOS transistor, the variable element model representing a change of a resistance value depending upon a drain voltage. As to the element model employed in this circuit simulation method, concrete modes similar to those of the first aspect of the present invention may be employed.

Effects which may be achieved by the present invention will now be briefly explained.

The error between the actual measurement value of the element characteristic of the high voltage MOS transistor and the simulation value thereof can be decreased, while the high voltage MOS transistor owns the low concentration impurity region between the channel region and the drain region.

The simulation precision as to the circuit using the high voltage MOS transistor having the low concentration impurity region between the channel region and the drain region can be improved.

Other objects, features and advantages of the invention will become apparent from the following description of the embodiments of the invention taken in conjunction with the accompanying drawings.

### BRIEF DESCRIPTION OF THE DRAWINGS

FIG. 1 is an explanatory diagram for explaining a longitudinal sectional structure of a high voltage MOS transistor.

FIG. 2 is an explanatory diagram for explaining an element model in a circuitry manner according to the invention, in which the high voltage MOS transistor of FIG. 1 is defined by combing a plurality of element models (partial element models) with each other.

FIG. 3 is a characteristic diagram for graphically representing a DC characteristic of “Id” with respect to “Vds” as a simulation result with employment of the element model of the high voltage MOS transistor shown in FIG. 2.

FIG. 4 is a characteristic diagram for graphically showing a Vgs characteristic of a gate capacitance as a simulation result with employment of the element model of the high voltage MOS transistor indicated in FIG. 2.

FIG. 5 is a characteristic diagram for graphically indicating a DC characteristic of “Id” with respect to “Vds” as a simulation result when the high voltage MOS transistor is represented by way of a standard MOS model of “BSiM3” as a comparison example.

FIG. 6 is a characteristic diagram for graphically indicating a Vgs characteristic of a gate capacitance as a simulation result when the high voltage MOS transistor is represented by way of a standard MOS model of “BSiM3” as a comparison example.

FIG. 7 is an explanatory diagram for explaining an element model in the case that a JFET model is employed as another usable variable element model instead of a variable resistance model.

FIG. 8 is an explanatory diagram for explaining an element model in the case that a MOS transistor model is employed as another usable variable element model instead of a variable resistance model.

FIG. 9 is an explanatory diagram for explaining an element model in the case that a voltage-controlled current source model is employed as another usable variable element model instead of a variable resistance model.

FIG. 10 is an explanatory diagram for exemplifying data as to the element model of the high voltage MOS transistor.

FIG. 11 is an explanatory diagram for exemplifying data as to a partial element model, which is observed as another data.

FIG. 12 is an explanatory diagram for explaining a circuit simulation with employment of the element model.

FIG. 13 is a flow chart for describing a process flow operation of the circuit simulation.

FIG. 14 is a flow chart for describing developing steps of a semiconductor integrated circuit, which indicates positioning of the circuit simulation in the developing steps of the semiconductor integrated circuit.

FIG. 15 is an explanatory diagram for explaining a computer readable recording medium which has recorded thereon data as to the element model of the high voltage MOS transistor.

FIG. 16 is an explanatory diagram for illustratively showing another relationship between a computer apparatus and a recording medium for recording thereon model types, model parameters, and the like.

### DESCRIPTION OF THE EMBODIMENTS

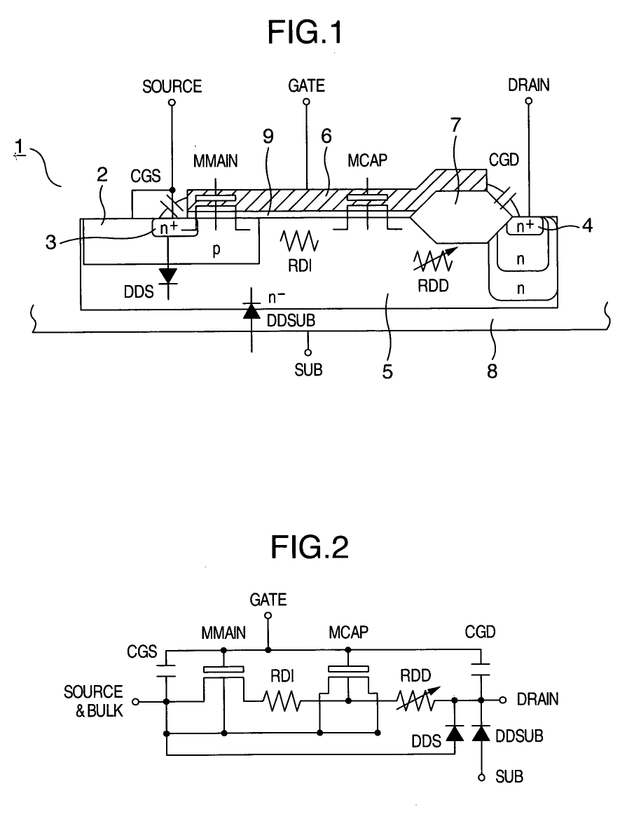

FIG. 1 schematically indicates a longitudinal sectional structure of a high voltage MOS transistor 1. The high voltage MOS transistor 1 shown in this drawing is constructed of an n-channel type MOS transistor in such a manner that an n⁺ type source electrode 3 has been formed in a channel region 2 functioning as a p type diffusion region, and an n⁻ type low concentration impurity region 5 has been formed between an n⁺ type drain electrode 4 and a channel region 2. A gate electrode 6 is formed via a gate oxide film 9 on both the channel region 2 and the low concentration impurity region 5. The drain electrode 4 is electrically separated from the gate electrode 6 by way of a LOCOS (Localized Oxidation of Silicon) 7. The above-explained low concentration impurity region 5 has been formed in a semiconductor substrate (SUB:substrate) 8. A portion which is overlapped via the gate oxide film 9 with the low concentration impurity region 5 constitutes an overlap region. The low concentration impurity region 5 increases a blocking voltage between the drain electrode 4 and the source electrode 3, and the LOCOS 7 increases a blocking voltage between the drain electrode 4 and the gate electrode 6. It should be understood that the structure of the low concentration impurity region 5 is not limited only to such a structure for covering the channel region 2, but also this low concentration impurity region 5 may be alternatively arranged between the channel region 2 and the drain region 4.

FIG. 2 shows an element model in a circuitry manner, in which the high voltage MOS transistor 1 of FIG. 1 is defined by combining a plurality of element models (partial element models). A correspondence relationship between the partial element models and portions of the high voltage MOS transistor is represented in FIG. 1.

The element model of the high voltage MOS transistor is defined based upon a MOS model “MMAIN”, a capacitor model “MCAP”, a fixed resistor model “RDI”, a variable resistor model “RDD” as a variable element model, a diode model “DDSUB” provided between the drain electrode and the substrate, a diode model “DDS” provided between the drain electrode and the source electrode, an overlap capacitor model “CGD” provided between the gate electrode and the drain electrode, and an overlap capacitor model “CGS” provided between the gate electrode and the source electrode.

The above-described MOS model MMAIN represents a main characteristic with respect to the channel region 2 of the high voltage MOS transistor 1. This MOS model MMAIN is defined by employing, for instance, an n-channel type MOS transistor of BSiM3. It should be understood that since a MOS transistor model of BSiM3 is known in this technical field, for example, is described in “BSiM3v3.2.2 Manual” issued from the University of California in 1999, a detailed description thereof is omitted.

The capacitor model MCAP represents a capacitance characteristic of the overlap region of the high voltage MOS transistor 1. This capacitor model MCAP is defined by using, for example, a p-channel type MOS transistor model of BSiM3. Since the MOS capacitor model is expressed by employing such a MOS capacitor model having a different conductivity type with respect to that of the MOS model, this capacitor MOS model is suitably adapted to an actual device structure.

The variable resistor model RDD is assumed as such a variable element model which represents a change in a resistance value depending upon a drain voltage between the drain electrode 4 and the channel region 2 in the low concentration impurity region 5 of the high voltage MOS transistor 1. In other words, this variable element model corresponds to a non-linear resistor model as a function of the drain voltage. The fixed resistor model RDI bears a part in a portion of a resistor in the low concentration impurity region 5. In this example, the variable resistor model RDD is connected to the side of the drain electrode 4 while sandwiching the capacitor model MCAP, and the fixed resistor model RDI is connected to the side of the channel region 2. In an actual case, both the resistance component of the low concentration impurity region 5 and the capacitance component of the overlap region are present in the distributed constant manner. When this distributed constant manner of the resistance/capacitance components is considered, such an expression that this resistance component is expressed by both the variable resistor and the fixed resistor may be properly adapted to an actual device characteristic, as compare with such an expression that this resistance component is expressed only by the variable resistor. Then, this resistance component is not expressed by a plurality of variable resistors, but expressed by a combination between the variable resistor and the fixed resistor, and also, is not represented by a distributed constant resistor, so that a large increase in process time by a computer can also be suppressed.

A model equation of the variable resistor model RDD corresponds to a novel model equation, and is represented by, for example, the below-mentioned set of equations (1). In the equations (1), symbol “*” shows a multiplication symbol. A description is made of parameters employed in the model equation of the variable resistor model RDD of the below-mentioned equations (1) as follows:
A parameter “RDD0” shows a drain resistance value per a unit width (1 μm);
A parameter “XRD” indicates a division ratio of RDD to RDI;
A parameter “DRDW” indicates a Width offset value;
A parameter “PRDW” shows a drain resistor Width dependent coefficient;
A parameter “PRDDVDA” indicates a Vds dependent characteristic primary coefficient of a drain resistor;
A parameter “PRDDVDB” indicates a Vds dependent characteristic secondary coefficient of a drain resistor;

A parameter “PRDDVGA” indicates a Vgs dependent characteristic primary coefficient of a drain, resistor;
A parameter “WRDDVDA” shows a Width dependent characteristic of PRDDVDA;
A parameter “WRDDVDB” indicates a Width dependent characteristic of PRDDVDB;

A parameter “TRDD1” represents a temperature primary coefficient of RDD0;
A parameter “TRDD2” shows a temperature secondary coefficient of RDD0;
A parameter “TRDDVDA1” indicates a temperature primary coefficient of PRDDVDA;
A parameter “TRDDVDA2” shows a temperature secondary coefficient of PRDDVDA;
A parameter “TRDDVDB1” indicates a temperature primary coefficient of PRDDVDA;
A parameter “TRDDVDB2” shows a temperature secondary coefficient of PRDDVDA;
A parameter “Width” indicates a device width;
A parameter “Temp” indicates a temperature when a simulation is carried out;
A parameter “Tnom” indicates a reference temperature;
A parameter “deltaT” represents a value of Temp-Tnom;
A parameter “vds” represents a drain-to-source voltage;
A parameter “vgs” shows a gate-to-source voltage.

It should be understood that the above-described primary coefficient implies a coefficient of a primary variable of a secondary model equation, whereas the above-described secondary coefficient implies a coefficient of a secondary variable of the secondary model equation.

$$\begin{matrix}Rdd = RDD0 * ( 1 - XRD ) * {Rdd}_{v} * {Rdd}_{size} * {Rdd}_{temp} \\ {Rdd}_{v} = \begin{matrix}1 + ( Pr {ddvda}_{temp} * \sqrt{vds} + \\ Pr {ddvdb}_{temp} * vds ) * ( 1 + \frac{PRDDVGA}{( {vgs}^{2} + 1 )} ) \end{matrix} \\ {Rdd}_{size} = \frac{1 e - 6}{( Width * PRDW - DRDW )} \\ {Rddvda}_{nom} = PRDDVDA * ( 1 + ( \frac{WRDDVDA}{Width} ) ) \\ {Rddvdb}_{nom} = PRDDVDB * ( 1 + ( \frac{WRDDVDB}{Width} ) ) \\ {Rdd}_{temp} = ( 1 + TRDD1 * deltaT + TRDD2 * {deltaT}^{2} ) \\ Pr {ddvda}_{temp} = \begin{matrix}{Rrddvda}_{nom} * ( 1 + TRDDVDA1 * deltaT + \\ TRDDVDA2 * {deltaT}^{2} ) \end{matrix}\end{matrix}$$

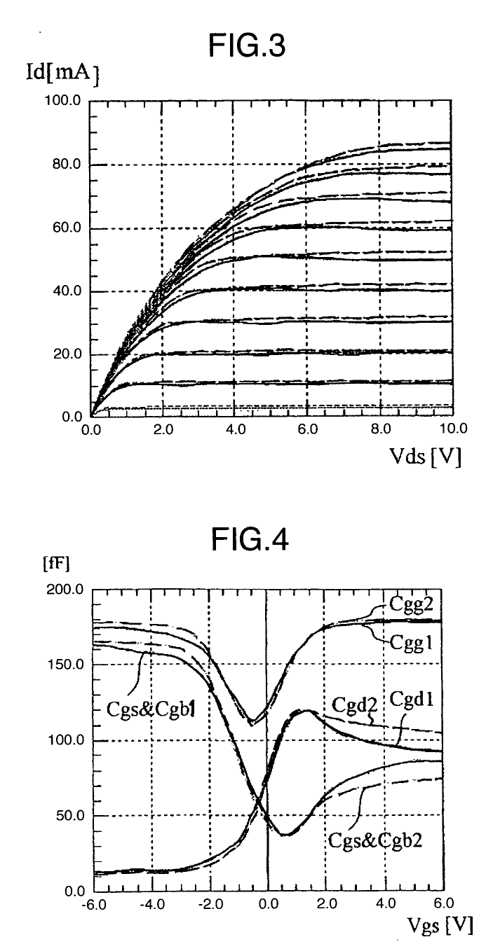

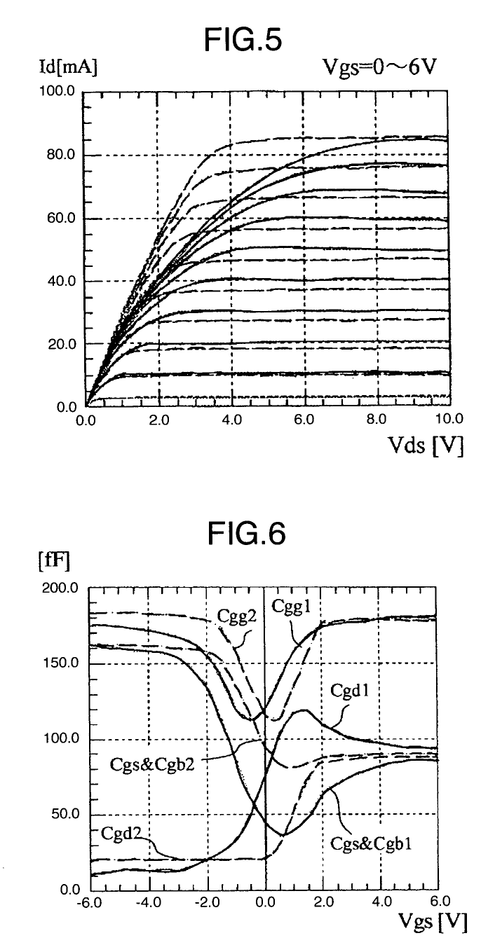

FIG. 3 and FIG. 4 exemplifies a simulation result obtained by employing the element model of the high voltage MOS transistor 1 shown in FIG. 2. FIG. 3 indicates a DC characteristic of an Id (drain current) with respect to Vds (drain-to-source voltage). FIG. 4 indicates Vgs (gate-to-source voltage) of a gate capacitance. Symbol “Cgg” implies a gate capacitance; symbol “Cgd” implies a gate-to-drain capacitance; symbol “Cgs” implies a gate-to-source capacitance; and symbol “Cgb” implies a gate-to-substrate capacitance. In the drawings, a solid line shows an actual measurement value with respect to an actual device, and a broken line represents a simulation value. As apparent from these drawings, the simulation values are approximated to the actual measurement values. FIG. 5 and FIG. 6 show simulation results when the high voltage MOS transistor 1 is expressed by the standard MOS model of BSiM3 (when high voltage MOS transistor 1 is expressed only by MMAIN) as a comparison example. FIG. 5 indicates a DC characteristics of “Id” with respect to “Vds.” FIG. 6 shows a Vgs characteristic of a gate capacitance. In the case of FIG. 5 and FIG. 6, simulation values own large errors with respect to actual measurement values.

The variable resistor model-RDD is operated in such a way that this variable resistor model RDD compensates that a voltage at an edge portion of the channel region 2 located adjacent to the low concentration impurity region 5 is changed by being influenced by not only the gate voltage, but also the drain voltage, the gate size, and the temperature, which may reduce the error between the actual measurement value of the element characteristic of the high voltage MOS transistor and the simulation value thereof. Since the above-described element model further contains the diode model DDS, the diode model DDSUB, the overlap capacitor model CGS, and also, the overlap capacitor model CGD, this element model may be adapted to the actual device characteristic. In particular, as previously explained, since the resistance component of the low concentration impurity region 5 formed between the channel region and the drain region is expressed by both the fixed resistor and the variable resistor, this element model may be adapted to actual device characteristic, and also may suppress a large increase of the computer processing time.

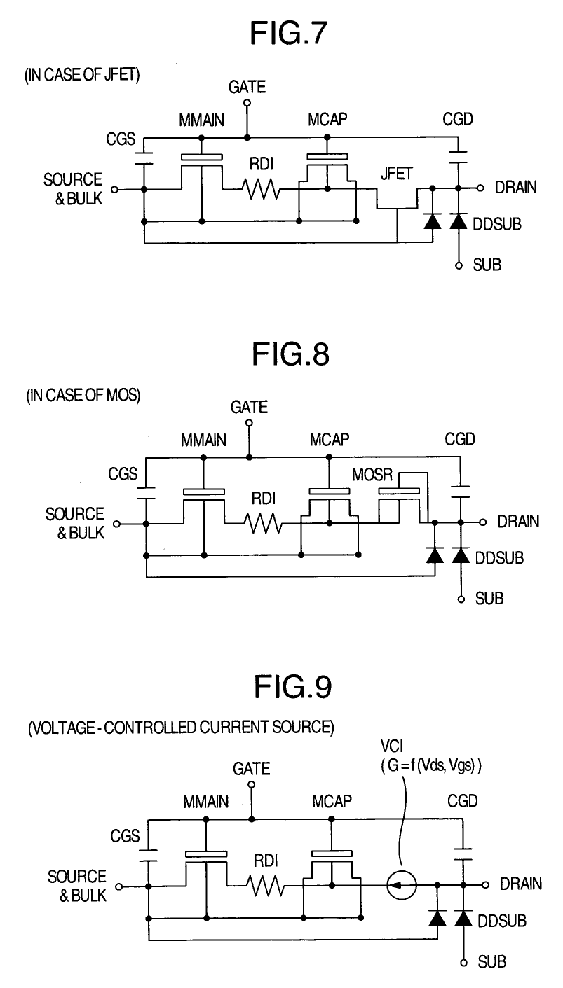

FIG. 7 to FIG. 9 show other variable element models which may be employed instead of the variable resistor model. In FIG. 7, a junction FET (JFET) model is employed as the variable element model. In the JFET model, a depletion layer is controlled by a junction portion voltage, so that a conductance is variable. In FIG. 8, a MOS transistor model MOSR is employed as the variable element model. In the MOS transistor model MOSR, a conductance is variable by a drain voltage. In FIG. 9, a voltage-controlled current source model VCI (conductance G=f (Vds, Vgs)) is employed as the variable element model. In the voltage-controlled current source model VCI, a current value is variable by either Vds or Vgs of the high voltage MOS transistor 1. Although not shown in the drawing, as other variable element models, a voltage-controlled voltage source model in which a voltage value is variable by either Vds or Vgs of the high voltage MOS transistor 1 may be alternatively employed; a current-controlled voltage source model in which a voltage value is controlled by Ids of the high voltage MOS transistor 1 may be alternatively employed; and a current-controlled current source model in which a current value is controlled by Ids of the high voltage MOS transistor 1 may be alternatively employed.

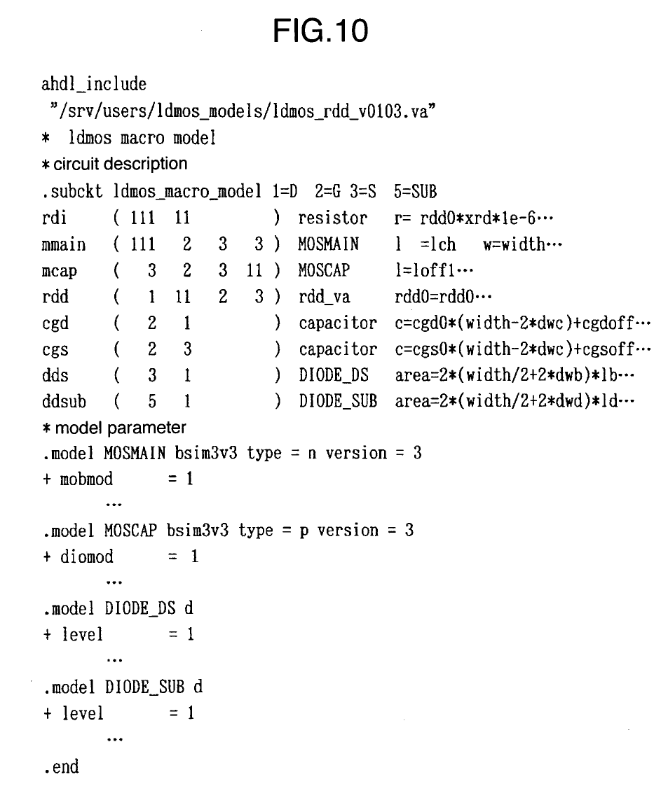

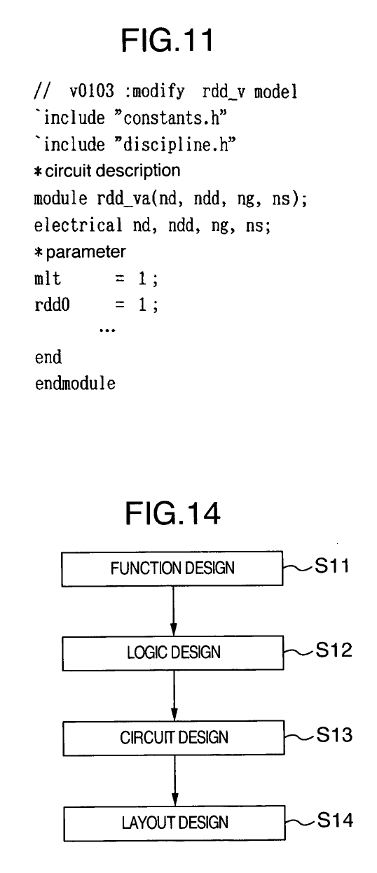

FIG. 10 and FIG. 11 exemplify data as to the element models of the high voltage MOS transistor 1 shown in FIG. 1 and FIG. 2. In FIG. 10, firstly, a reference destination of another data (variable resistor model equation of FIG. 11) is indicated, and subsequently, the circuits constituted by the partial element models explained in FIG. 1 and FIG. 2 are defined, namely, the model equations are defined. Subsequent to the definition, model parameter values of the partial element models are defined. Although there is no specific limitation in the data example of FIG. 10, both the circuit description of the variable resistor model and the model parameter are defined as an rdd-va module in the form of another file at the reference destination of another data. Apparently, all of the circuit description and the model parameter may be alternatively defined by employing one file. A description example of another file is shown in FIG. 11.

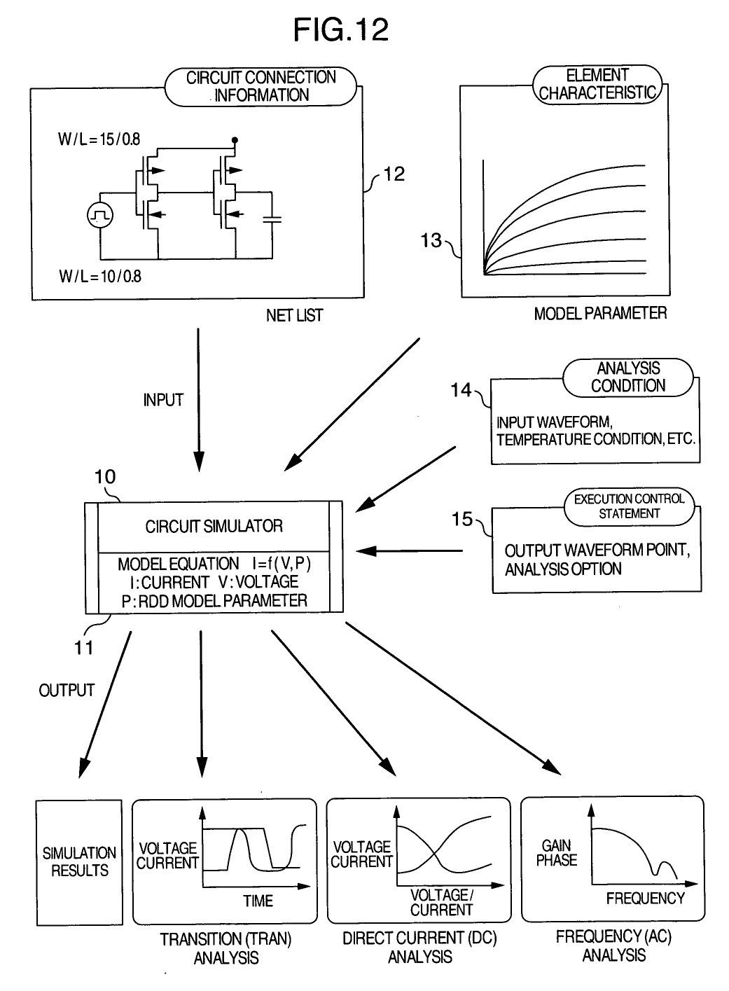

FIG. 12 is an explanatory diagram of a circuit simulation using the above-described element model. A circuit simulator 10 functioning as a circuit simulation program can be executed by a computer apparatus such as an engineering workstation. A model equation 11 of the element model is installed in the circuit simulator 10. As the model equation 11 to be installed, the above-explained model equation (equation (1)) of the element model of the high voltage MOS transistor according to the present invention in addition to model equations as to such element models as the existing bipolar transistor and the standard MOS transistor. In the circuit simulator 10, circuit connection information (net list) 12 of a simulation subject circuit; a model parameter 13 functioning as a circuit element characteristic; an analysis condition 14 such as an input waveform and a temperature condition; and an execution control statement 15 such as an output waveform point and an analysis option are installed. Within the above-explained model equation 11 and the above-described model parameter 13, both a model equation and a model parameter related to the high voltage MOS transistor 1 are given by the data as to the element model explained in FIG. 10 and FIG. 11. The circuit simulator 10 executes a circuit simulation by way of the Newton-Raphson's method, or the like with respect to the circuit specified in the net list 12 in accordance with the above-described input information so as to perform a transition analysis, a DC analysis, a frequency analysis, and so on.

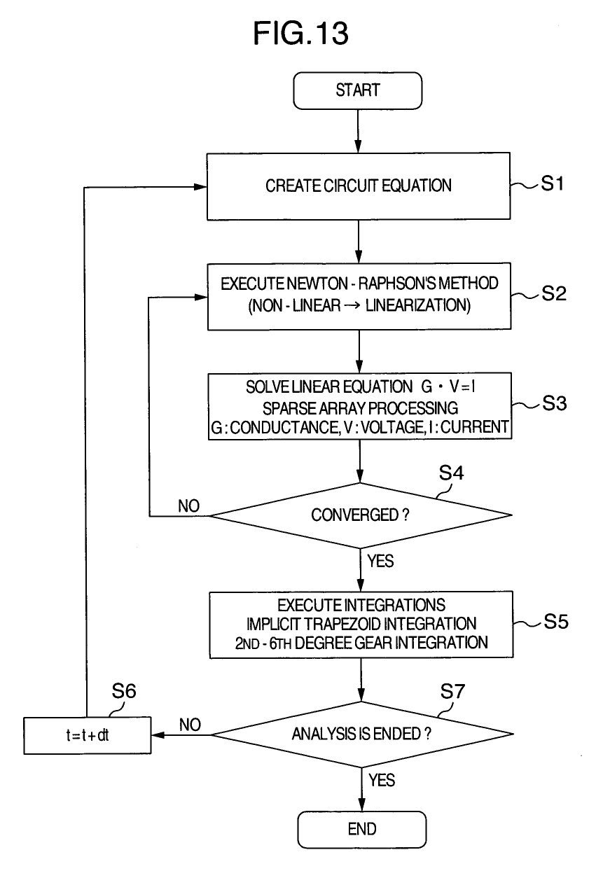

FIG. 13 describes a process flow operation of the circuit simulation. The circuit connection information 12, the analysis condition 14, the model parameter 13, and the like are entered, and then, a circuit equation is produced based upon the entered information (step S1). The circuit equation is produced based upon the connection information of the circuit and the model equation of the element. The parameter is substituted for the circuit equation, and a non-linear equation is approximated to a linear equation by way of the Newton-Raphson's method (step S2), and then, the linear equation is solved by executing a sparse array matrix process operation (step S3). The process operations defined in the steps S2 and S3 are repeatedly carried out until a solution of the linear equation is converged (step S4). The converged results are integrated (step S5), and an analysis time instant is advanced every “dt” until the analysis time is reached (step S6), and the above-explained process operations are repeatedly carried out (step S7).

FIG. 14 indicates positioning of a circuit simulation in developing steps of a semiconductor integrated circuit. The development of the semiconductor integrated circuit is mainly subdivided into a function design step (S11), a logic design step (S12), a circuit design step (S13), and also, a layout design step (S14). In the function design step (S11), a decision is made how to install the necessary functions and the necessary performance in a semiconductor integrated circuit (LSI circuit) which will be manufactured. In the logic design step (S12), the functions of the respective circuit blocks (functional modules) determined in the function design step (S11) are realized by a combination of basic logic circuits (gate circuits) which are represented by an electric flow. In an actual designing operation, the functions of the respective circuit blocks (function modules are realized by employing a language such as HDL (hardware description language). In the circuit design step (S13), a decision is made how to construct the LSI circuit by combining semiconductor elements having different characteristics, and then, a verification is carried out so as to optimize a circuit arrangement by a circuit simulation with employment of a computer apparatus. In the layout design step (S14), a mode for effectively arranging the circuits where the circuit design step (S13) has been completed on a semiconductor chip is determined.

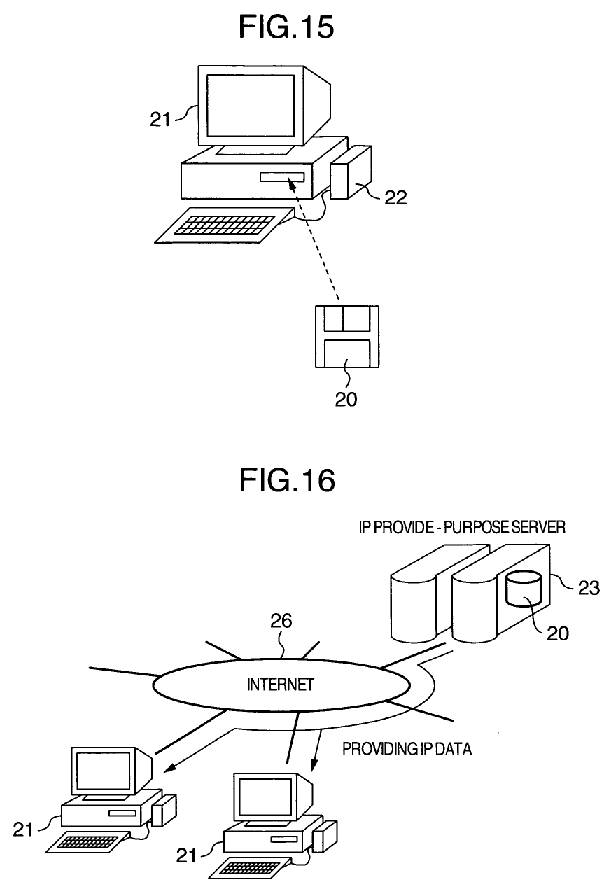

FIG. 15 illustratively shows a computer readable recording medium 20. The recording medium 20 shown in this drawing is a removable recording medium. For example, this recording medium 20 corresponds to a magnetic tape, a flexible disk, a hard disk, a CD-ROM, an MO (magneto optical disk), a DVD etc. The data as to the element model, for instance, model equations and model parameters have been recorded on this recording medium 20, which can be read by a computer system 21 such as an engineering workstation. While the model equations and the model parameters read out from the recording medium 20 are stored into a fixed disk apparatus 22, when a system is developed by utilizing the computer system 21, both the model equations and the model parameters are read in a memory of the computer system 21 so as to be used.

FIG. 16 illustratively shows another relationship between the computer system 21 and the recording medium 20 which has recorded the model equations, the model parameters and the like. The recording medium 20 is stored in a sever 23 which provides both the model equations and the model parameters. The server 23 is connected via a network such as the Internet to the computer system 21 such as an engineering workstation. Both the model equations and the model parameters which have been stored in the recording medium 20 are downloaded to the computer system 21. The downloaded model equations and the downloaded model parameters are stored in either a local hard disk or a local memory so as to be used in the system developing operation.

Since the element model of the above-described high voltage MOS transistor 1 is stored in the computer-readable recording medium 20 so as to be provided, the precision of the circuit simulation with respect to such a circuit using the high voltage MOS transistor 1 can be readily improved, and also, the provided element model of the high voltage MOS transistor 1 can contribute to improve reliability of designing the circuit with employment of the high voltage MOS transistor and also can contribute to shorten the designing terms.

Alternatively, both the above-explained model equations and the above-explained model parameters may be stored in the recording medium 20 in combination with IP module data of an function module using the high voltage MOS transistor 1 and the like so as to be provided. In addition, these model equations and model parameters may be alternatively provided so as to design a circuit, or to develop a semiconductor integrated circuit.

While the present invention made by the Inventors has been previously explained based upon the embodiment modes in the concrete manner, the present invention is not limited only to these embodiment modes, but may be modified, changed, and substituted without departing from the technical spirit and scope of the present invention.

For instance, the model equation of the variable resistor element is not limited only to the above-explained equation, but may be properly changed. For example, a degree of a high degree function which is employed so as to produce a model equation may be alternatively changed from the above-described degree, and then, the changed high degree function may be used so as to determine the model equation. Alternatively, a high voltage MOS transistor may be manufactured by employing such a structure that a gate electrode thereof is not overlapped with a low concentration impurity region. In this alternative case, MCAP is no longer required.

1. A recording medium for recording thereon computer-readable data as to an element model of a high voltage MOS transistor having a low concentration impurity region between a channel region thereof an a drain region thereof, wherein
said element model includes a variable element model representing a change of a resistance value between the drain electrode and the channel region of the high voltage MOS transistor depending upon a drain voltage.

2. A recording medium as claimed in claim 1, wherein
said change of the resistance value also depends upon a voltage applied to a gate electrode of the high voltage MOS transistor.

3. A recording medium as claimed in claim 2, wherein
said change of the resistance value also depends upon a gate size of the high voltage MOS transistor, and a temperature.

4. A recording medium as claimed in claim 3, wherein
said variable element model corresponds to a variable resistor model.

5. A recording medium as claimed in claim 3, wherein
said variable element model corresponds a junction FET model.

6. A recording medium as claimed in claim 3, wherein
said variable element model corresponds to either a variable current source model or a variable voltage source model.

7. A recording medium as claimed in claim 3, wherein
said high voltage MOS transistor has an overlap region which is overlapped via a gate oxide film with the gate electrode in said low concentration impurity region.

8. A recording medium as claimed in claim 7, wherein
said element model is further comprised of:
a MOS model which represents a major characteristic with respect to the channel region of said high voltage MOS transistor;
a capacitor model which represents a capacitance characteristic of said overlap region of said high voltage MOS transistor; and
a fixed resistor model which is arranged in series with said variable element model; and wherein said variable element model is arranged in series with said capacitor model.

9. A recording medium as claimed in claim 8, wherein
said MOS capacitor model corresponds to a MOS capacitor model having a different conductivity type with respect to that of said MOS model.

10. A recording medium as claimed in claim 9, wherein
said element model is further comprised of:
a diode model provided between the drain electrode and a substrate;
a diode model provided between the drain electrode and a source electrode;
an overlap capacitor model provided between the gate electrode and the drain electrode; and
an overlap capacitor model provided between the gate electrode and the source electrode.

11. A circuit simulation method for executing a circuit simulation with employment of an element model of a high voltage MOS transistor having a low concentration impurity region between a channel region thereof and a drain electrode thereof wherein:
said element model includes a variable element model between the drain electrode and a source electrode of the high voltage MOS transistor, said variable element model representing a change of a resistance value depending upon a drain voltage.

12. A circuit simulation method as claimed in claim 11, wherein
said change of the resistance value also depends upon a voltage applied to a gate electrode of the high voltage MOS transistor.

13. A circuit simulation method as claimed in claim 12, wherein
said change of the resistance value also depends upon a gate size of the high voltage MOS transistor, and a temperature.

14. A circuit simulation method as claimed in claim 13, wherein
said high voltage MOS transistor has an overlap region which is overlapped via a gate oxide film with the gate electrode in said low concentration impurity region.

15. A circuit simulation method as claimed in claim 14, wherein
said element model is further comprised of:
a MOS model which represents a major characteristic with respect to the channel region of said high voltage MOS transistor;
a capacitor model which represents a capacitance characteristic of said overlap region of said high voltage MOS transistor; and
a fixed resistor model which is arranged in series with said variable element model; and wherein:
said variable element model is arranged in series with said capacitor model.

16. A circuit simulation method as claimed in claim 15, wherein
said MOS capacitor model corresponds to a MOS capacitor model having a different conductivity type with respect to that of said MOS model.
